(19) United States
(12) Patent Application Publication
(10) Pub. No.: US 2024/0079854 A1
(43) Pub. Date: Mar. 7, 2024

(54) Vertical Cavity Surface Emitting Laser, Electronic Device with Same and Manufacturing Method for Same

(71) Applicant: Shenzhen Berxel Photonics Co., Ltd., Shenzhen City (CN)

(72) Inventors: Jiaxing WANG, Shenzhen City (CN); Qinpei LIU, Shenzhen City (CN)

(21) Appl. No.: 18/132,413

(22) Filed: Apr. 9, 2023

(30) Foreign Application Priority Data
Sep. 5, 2022 (CN) 202211078729.1

(51) Int. Cl. H01S 5/183; H01S 5/028; H01S 5/042; H01S 5/125; H01S 5/30

(52) U.S. Cl. CPC H01S 5/18311; H01S 5/0282; H01S 5/04256; H01S 5/125; H01S 5/3013

(57) ABSTRACT

The present disclosure provides a vertical cavity surface emitting laser, an electronic device with the same, and a manufacturing method for the same. The vertical cavity surface emitting laser includes a substrate layer, a first electrode layer, a first reflector layer, an active layer, an oxide layer, a second reflector layer, a second electrode layer, and a passivation layer, wherein the oxide layer includes a wedge-shaped structure on which an oxide aperture is formed, and the thickness of the center of the wedge-shaped structure is smaller than the thickness of its outer sides. The vertical cavity surface emitting laser provided by the present disclosure can play roles in reducing the photon scattering loss, reducing the parasitic capacitance, and increasing the modulation bandwidth of the laser.

### CROSS REFERENCE TO RELATED APPLICATION

The present disclosure claims the benefit of priority to Chinese patent application No. 202211078729.1, filed on Sep. 5, 2022 to China National Intellectual Property Administration, which are incorporated herein by reference in its entirety.

### TECHNICAL FIELD

The present disclosure generally relates to the technical field of photoelectric devices, in particular, to a vertical cavity surface emitting laser (VCSEL), an electronic device with the same, and a manufacturing method for the same.

### BACKGROUND

A vertical cavity surface emitting laser (VCSEL) can be widely applied to the fields such as optical communications, 3D sensing, and LiDAR due to various advantages such as small size, low power consumption, easy integration and high coupling efficiency.

However, there is a thicker circular arc on an in the related art, the oxide aperture of a vertical cavity surface emitting laser has a thick circular arc. By such a structure, the photon scattering loss can be increased, and meanwhile, the modulation bandwidth of the laser can be reduced.

### SUMMARY

In view of above-mentioned defects or disadvantages in the related art, it is desired to design a vertical cavity surface emitting laser, an electronic device with the same, and a manufacturing method for the same, by which the photon scattering loss can be reduced, and the modulation bandwidth of the laser can be increased.

In a first aspect, the present disclosure provides a vertical cavity surface emitting laser, wherein the vertical cavity surface emitting laser includes a substrate layer, a first electrode layer, a first reflector layer, an active layer, an oxide layer, a second reflector layer, a second electrode layer, and a passivation layer, wherein the oxide layer includes a wedge-shaped structure on which an oxide aperture is formed, and the thickness of the center of the wedge-shaped structure is smaller than the thickness of its outer sides.

Optionally, in some embodiments of the present disclosure, the first electrode layer is located under the substrate layer, and the first reflector layer, the active layer, the oxide layer, the second reflector layer, the second electrode layer and the passivation layer are sequentially stacked on the substrate layer.

Optionally, in some embodiments of the present disclosure, the first electrode layer and the passivation layer are located under the substrate layer, and the first reflector layer, the active layer, the oxide layer, the second reflector layer and the second electrode layer are sequentially stacked on the substrate layer.

Optionally, in some embodiments of the present disclosure, the first reflector layer and the second reflector layer include at least one of a distributed Bragg reflector layer and/or a high contrast grating layer respectively.

Optionally, in some embodiments of the present disclosure, the first electrode layer and the second electrode layer respectively include one N-contact layer and one P-contact layer.

Optionally, in some embodiments of the present disclosure, the active layer includes any one of a single quantum well layer and a multiple quantum well layer.

In a second aspect, the present disclosure provides an electronic device, wherein the electronic device includes the vertical cavity surface emitting laser of any one in the first aspect.

In a third aspect, the present disclosure provides a manufacturing method for a vertical cavity surface emitting laser, wherein the method is applied to the vertical cavity surface emitting laser of any one in the first aspect, and the method includes:
providing a substrate layer; and
forming a first reflector layer, an active layer, an oxide layer, a second reflector layer, a second electrode layer and a passivation layer on the substrate layer, and forming the first electrode layer under the substrate layer, wherein the oxide layer is obtained by oxidizing AlₓGa₁₋ₓAs in which the content of an aluminum composition is gradually varied, x represents aluminum composition, the aluminum composition in the middle of the oxide layer is the highest, and the aluminum composition on upper and lower sides thereof is gradually reduced.

Optionally, in some embodiments of the present disclosure, the AlₓGa₁₋ₓAs layer has a gradually varied content of the aluminum composition and has a thickness ranging from 5 nm to 20 nm.

It can be seen from the above-mentioned technical solutions, the embodiments of the present disclosure have the following advantages:
the embodiments of the present disclosure provide a vertical cavity surface emitting laser, an electronic device with the same, and a manufacturing method for the same. By designing the element composition of the oxide layer of the vertical cavity surface emitting laser, a wedge-shaped oxide aperture is formed after the oxidization is completed, wherein the thickness of the center of the wedge-shaped structure is smaller than the thickness of its outer sides, and therefore, the wedge-shaped structure may play roles in reducing the photon scattering loss, reducing the parasitic capacitance, and increasing the modulation bandwidth of the laser.

### BRIEF DESCRIPTION OF FIGURES

By reading detailed descriptions of nonrestrictive embodiments with reference to the accompanying drawings, other features, objectives and advantages of the present disclosure will become more apparent:

FIG. 1 is a schematic diagram of a sectional structure of a vertical cavity surface emitting laser in the related art;

FIG. 2 is a schematic diagram of a sectional structure of another vertical cavity surface emitting laser in the related art;

FIG. 3 is a schematic diagram of a sectional structure of a vertical cavity surface emitting laser provided in an embodiment of the present disclosure;

FIG. 4 is a schematic diagram of a sectional structure of another vertical cavity surface emitting laser provided in an embodiment of the present disclosure;

FIG. 5 is a structural block diagram of an electronic device provided in an embodiment of the present disclosure;

FIG. 6 is a schematic diagram of a basic process of a manufacturing method for a vertical cavity surface emitting laser provided in an embodiment of the present disclosure; and

FIG. 7 is a schematic diagram of the gradual variation of aluminum composition provided in an embodiment of the present disclosure.

### DETAILED DESCRIPTION

In order to make the skilled in the art better understand solutions in the present disclosure, the technical solutions in the embodiments of the present disclosure will be described clearly and completely below in conjunction with the accompanying drawings in the embodiments of the present disclosure. Obviously, the described embodiments are only a part of the embodiments of the present disclosure, not all the embodiments. Based on the embodiments of the present disclosure, all other embodiments obtained by those of ordinary skill in the art without creative work will fall within the protection scope of the present disclosure.

Terms “first”, “second”, “third”, “fourth”, etc. (if available) in the specification and claims of the present disclosure and the above-mentioned accompanying drawings are used for distinguishing similar objects, and are unnecessarily used for describing a specific sequential or chronological order. It should be understood that the data used in such a way are interchangeable where appropriate, such that the embodiments of the present disclosure described herein can be implemented in other sequences, in addition to the sequences illustrated or described herein.

In addition, the terms “including” and “having” and any variants thereof are intended to cover a non-exclusive inclusion. For example, a process, method, system, product, or device including a series of steps or modules is unnecessarily limited to the clear listing of those steps or modules, and may include other steps or modules which are not clearly listed or are inherent for the process, method, product or device.

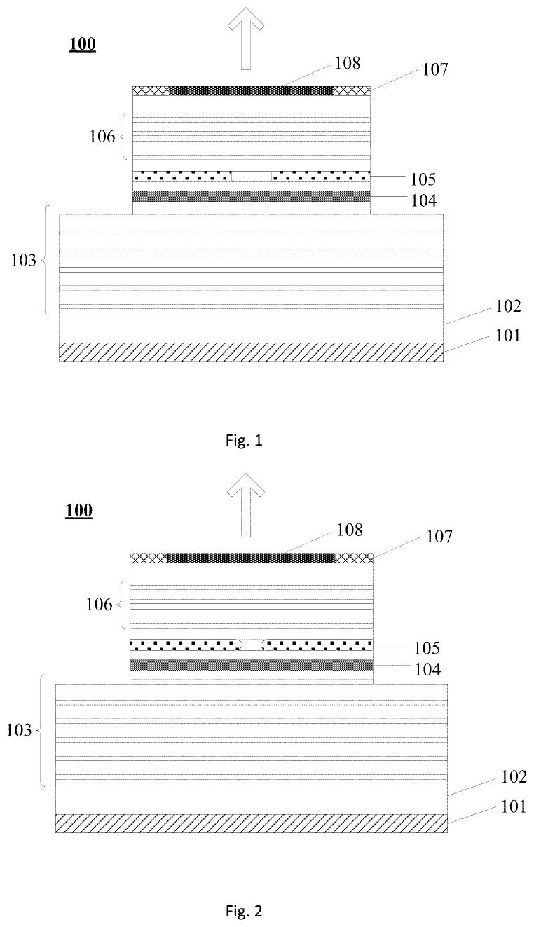

In order to better understand the embodiments of the present disclosure, a description will be performed now in conjunction with the schematic diagram of a vertical cavity surface emitting laser in the related art shown in FIG. 1 and FIG. 2. As shown in FIG. 1, the vertical cavity surface emitting laser 100 in the related art includes a cathode 101, a substrate layer 102, an N-type distributed Bragg reflector layer 103, an active layer 104, an oxide layer 105, a P-type distributed Bragg reflector layer 106, a anode 107, and a passivation layer 108. It should be noted that, the oxide layer 105 is oxidized to form a structure that is conductive in the center and insulative on the outer sides, the oxide layer may play a role in limiting the current, allowing more current to flow into the central part of the active layer 104 to increase the carrier density, thus a high differential gain is obtained, and the modulation bandwidth of the laser is increased. As shown in FIG. 2, in the related art, adopted is a way of fixing an aluminum composition of a single layer, by which it tends to form a thicker circular arc structure in the center of the aperture after oxidation, thus, the photon scattering loss is increased, and meanwhile, the modulation bandwidth of the laser is reduced.

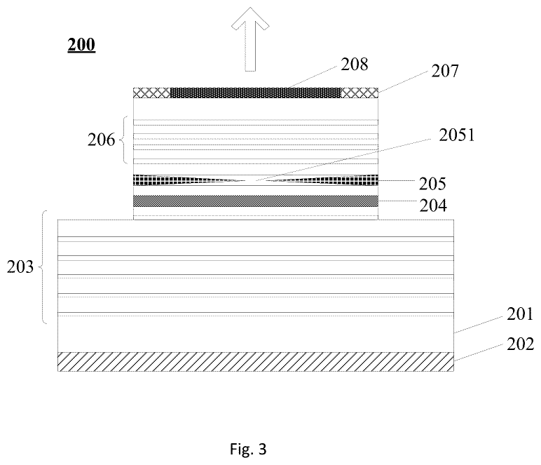

To this end, embodiments of the present disclosure provide a vertical cavity surface emitting laser, an electronic device with the same, and a manufacturing method for the same, which will be described in detail below with reference to FIG. 3 to FIG. 7.

Referring to FIG. 3 which is a schematic diagram of a sectional structure of a vertical cavity surface emitting laser provided in an embodiment of the present disclosure, this vertical cavity surface emitting laser 200 includes a substrate layer 201, a first electrode layer 202, a first reflector layer 203, an active layer 204, an oxide layer 205, a second reflector layer 206, a second electrode layer 207, and a passivation layer 208, wherein the oxide layer 205 includes a wedge-shaped structure on which an oxide aperture 2051 is formed, and the thickness of the center of the wedge-shaped structure is smaller than the thickness of its outer sides.

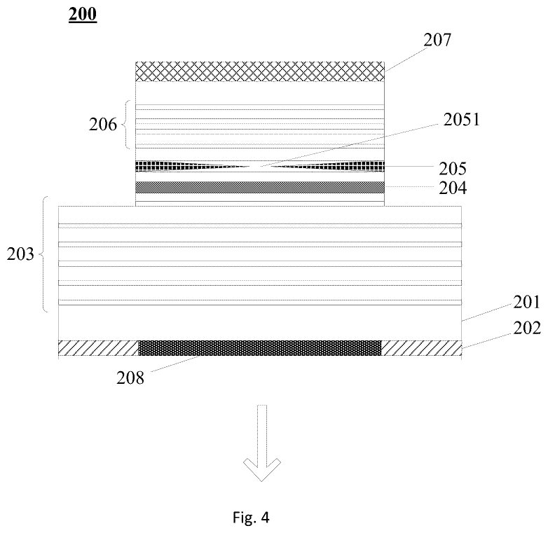

Optionally, the vertical cavity surface emitting laser 200 in the embodiment of the present disclosure includes, but is not limited to a top emission structure and a bottom emission structure. Using the top emission structure shown in FIG. 3 as an example, in this structure, the first electrode layer 202 is located under the substrate layer 201, and the first reflector layer 203, the active layer 204, the oxide layer 205, the second reflector layer 206, the second electrode layer 207 and the passivation layer 208 are sequentially stacked on the substrate layer 201. Using the bottom emission structure shown in FIG. 4 as another example, in this structure, the first electrode layer 202 and the passivation layer 208 are located under the substrate layer 201, and the first reflector layer 203, the active layer 204, the oxide layer 205, the second reflector layer 206 and the second electrode layer 207 are sequentially stacked on the substrate layer 201.

Optionally, in the embodiment of the present disclosure, the first reflector layer 203 and the second reflector layer 206 need to respectively include one N-type reflector layer and one P-type reflector layer. For example, the first reflector layer 203 is an N-type reflector layer, and the second reflector layer 206 is a P-type reflector layer. For another example, the first reflector layer 203 is a P-type reflector layer, and the second reflector layer 206 is an N-type reflector layer. Further, the first reflector layer 203 and the second reflector layer 206 may include at least one of a distributed Bragg reflector (DBR) layer and/or a high contrast grating (HCG) layer respectively. That is to say, both of the first reflector layer 203 and the second reflector layer 206 are distributed Bragg reflectors, or both of the first reflector layer 203 and the second reflector layer 206 are high contrast grating, or one of the first reflector layer 203 and the second reflector layer 206 is a distributed Bragg reflector, and the other one is a high contrast grating.

Optionally, in the embodiment of the present disclosure, the first electrode layer 202 and the second electrode layer 207 need to respectively include one N-contact layer and one P-contact layer. For example, the first electrode layer 202 is an N-contact layer, and the second electrode layer 207 is a P-contact layer. For another example, the first electrode layer 202 is a P-contact layer, and the second electrode layer 207 is an N-contact layer.

Optionally, in the embodiment of the present disclosure, the active layer 204 may include any one of a single quantum well layer and a multiple quantum well (MQW) layer, and is used for the stimulated radiation when being electrified.

An embodiment of the present disclosure provides a vertical cavity surface emitting laser. By designing the element composition of the oxide layer of the vertical cavity surface emitting laser, a wedge-shaped oxide aperture is formed after the component is oxidized, wherein the thickness of the center of the wedge-shaped structure is smaller than the thickness of its outer sides, and therefore, the wedge-shaped structure may play roles in reducing the photon scattering loss, reducing the parasitic capacitance, and increasing the modulation bandwidth of the laser.

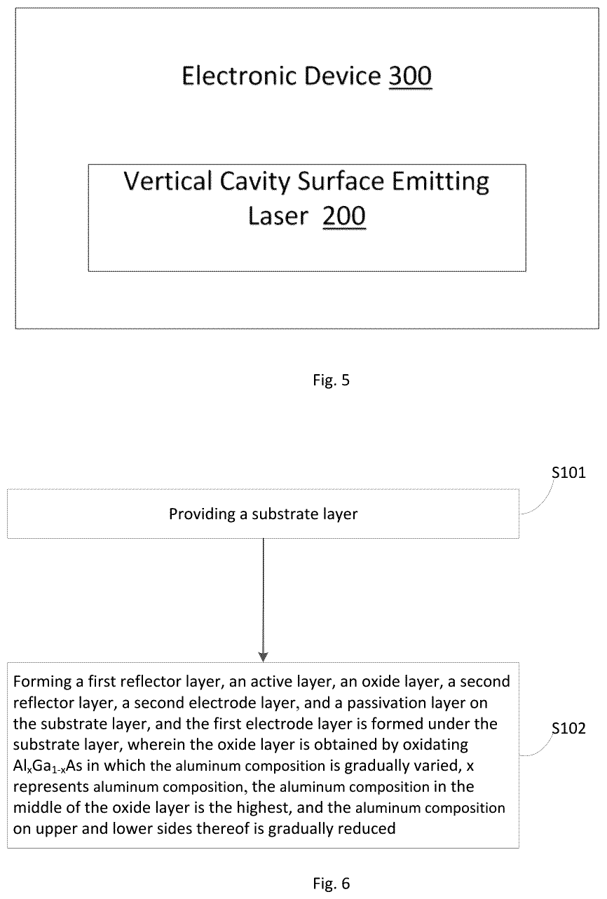

Based on the foregoing embodiment, referring to FIG. 5, it is a structural block diagram of an electronic device provided in an embodiment of the present disclosure. The electronic device 300 includes the vertical cavity surface emitting laser 200 in the embodiment corresponding to FIG. 3 to FIG. 4. For example, this electronic device 300 may include, but is not limited to an optical module and an integrated photoelectronic chip.

An embodiment of the present disclosure provides an electronic device. By designing the element composition of the oxide layer of the vertical cavity surface emitting laser of this electronic device, a wedge-shaped oxide aperture is formed after the oxidation is completed, wherein the thickness of the center of the wedge-shaped structure is smaller than the thickness of its outer sides, and therefore, the wedge-shaped structure may play roles in reducing the photon scattering loss, and reducing the parasitic capacitance, and increasing the modulation bandwidth of the laser.

Based on the foregoing embodiment, referring to FIG. 6, it is a schematic diagram of a basic process of a manufacturing method for a vertical cavity surface emitting laser provided in an embodiment of the present disclosure. This method can be applied to the vertical cavity surface emitting laser 200 in the embodiment corresponding to FIG. 3 to FIG. 4 and specifically includes the following steps:

S101, providing a substrate layer.

Exemplarily, the substrate layer 201 may be a GaAs substrate.

S102, forming a first reflector layer, an active layer, an oxide layer, a second reflector layer, a second electrode layer, and a passivation layer on the substrate layer, and the first electrode layer is formed under the substrate layer, wherein the oxide layer is obtained by oxidizing AlₓGa₁₋ₓAs in which the aluminum composition is gradually varied, x represents aluminum composition, the aluminum composition in the middle of the oxide layer is the highest, and the aluminum composition on upper and lower sides thereof is gradually reduced.

Exemplarily, using a structure shown in FIG. 3 as an example, the first electrode layer 202 is an N-contact layer, and the second electrode layer 207 is a P-contact layer. The first reflector layer 203 is an N-type distributed Bragg reflector layer, and the second reflector layer 206 is a P-type distributed Bragg reflector layer.

A specific manufacturing process is that:

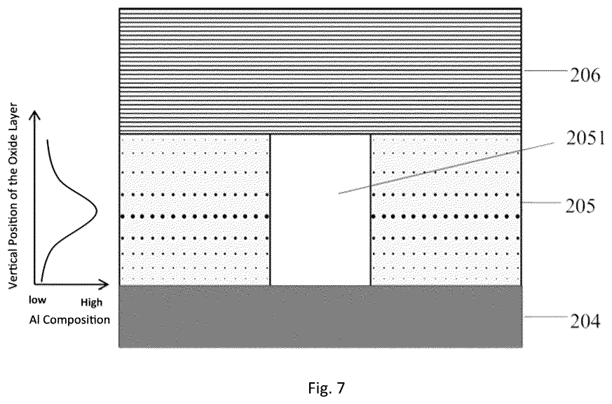

Firstly, periodic alternate growth is performed on the substrate layer 201 by adopting a metal organic chemical vapor deposition (MOCVD) technology or a molecular beam epitaxy (MBE) technology, etc. to form the first reflector layer 203, the active layer 204 and the AlₓGa₁₋ₓAs oxide layer 205 wherein the AlₓGa₁₋ₓAs oxide layer 205 has a gradual variation of aluminum composition as shown in FIG. 7, that is, the aluminum composition in the middle of the oxide layer 205 is the highest, and the aluminum composition on upper and lower sides thereof is gradually reduced.

Secondly, periodic alternate growth is performed again to form a second reflector layer 206; and then, lithography is performed to obtain a mesa pattern, etching is performed in an inductively coupled plasma (ICP) way to obtain a mesh structure, the AlₓGa₁₋ₓAs oxide layer 205 having a gradually varied aluminum composition is exposed, and then, the oxide aperture 2051 used to confine current is obtained in a wet oxidation way;

then, an N-contact layer corresponding to the first electrode layer 202 is obtained by using an electrode evaporation process, a P-contact layer corresponding to the second electrode layer 206 is obtained by using a magnetron sputtering process and a stripping process, and then, an electrode-plated laser is placed into a quick annealing furnace for annealing to achieve an alloy, so that good ohmic contact can be formed between an electrode and a semiconductor material, and electrical properties of a device are improved; and

Finally, the passivation layer 208 grows by a plasma enhanced chemical vapor deposition (PECVD) technology. The passivation layer 208 has a thickness of 3λ/2, where λ represents the laser emission wavelength, and thus, the vertical cavity surface emitting laser shown in FIG. 3 is obtained.

Optionally, the aluminum composition of the oxide layer in the embodiment of the present disclosure ranges from 90% to 98%.

Optionally, the AlₓGa₁₋ₓAs layer has a gradually varied content of the aluminum composition and has a thickness ranging from 5 nm to 20 nm in the embodiment of the present disclosure.

It should be noted that the description for steps or contents, which are the same as those in other embodiments, in the present embodiment may refer to the description in other embodiments, and is not repeated here again.

An embodiment of the present disclosure provides a manufacturing method for a vertical cavity surface emitting laser. By designing the element composition of the oxide layer of the vertical cavity surface emitting laser, a wedge-shaped oxide aperture is formed after the component is oxidized, wherein the thickness of the center of the wedge-shaped structure is smaller than the thickness of each of its outer sides, and therefore, the wedge-shaped structure may play roles in reducing the photon scattering loss, reducing the parasitic capacitance, and increasing the modulation bandwidth of the laser.

The above embodiments are merely intended to describe the technical solutions of the present disclosure, rather than to limit them. Although the present disclosure has been described in detail with reference to the aforementioned embodiments, it should be understood by those of ordinary skill in the art that they may still modify the technical solutions recited in each of the foregoing embodiments or equivalently substitute parts of technical features therein. These modifications or substitutions do not make the essences of the corresponding technical solutions depart from the spirit and scope of the technical solution in each of the embodiments of the present disclosure.

What is claimed is:

1. A vertical cavity surface emitting laser, wherein the vertical cavity surface emitting laser comprises a substrate layer, a first electrode layer, a first reflector layer, an active layer, an oxide layer, a second reflector layer, a second electrode layer, and a passivation layer, wherein the oxide layer comprises a wedge-shaped structure on which an oxide aperture is formed, and the thickness of the center of the wedge-shaped structure is smaller than the thickness of its outer sides.

2. The vertical cavity surface emitting laser of claim 1, wherein the first electrode layer is located under the substrate layer, and the first reflector layer, the active layer, the oxide layer, the second reflector layer, the second electrode layer and the passivation layer are sequentially stacked on the substrate layer.

3. The vertical cavity surface emitting laser of claim 1, wherein the first electrode layer and the passivation layer are located under the substrate layer, and the first reflector layer, the active layer, the oxide layer, the second reflector layer and the second electrode layer are sequentially stacked on the substrate layer.

4. The vertical cavity surface emitting laser of claim 1, wherein the first reflector layer and the second reflector layer comprise at least one of a distributed Bragg reflector layer and/or a high contrast grating layer respectively.

5. The vertical cavity surface emitting laser of claim 4, wherein the first electrode layer and the second electrode layer respectively comprise one N-contact layer and one P-contact layer.

6. The vertical cavity surface emitting laser of claim 5, wherein the active layer comprises any one of a single quantum well layer and a multiple quantum well layer.

7. An electronic device, wherein the electronic device comprises the vertical cavity surface emitting laser of claim 1.

8. The electronic device of claim 7, wherein the first electrode layer is located under the substrate layer, and the first reflector layer, the active layer, the oxide layer, the second reflector layer, the second electrode layer, and the passivation layer are sequentially stacked on the substrate layer.

9. The electronic device of claim 7, wherein the first electrode layer and the passivation layer are located under the substrate layer, and the first reflector layer, the active layer, the oxide layer, the second reflector layer, and the second electrode layer are sequentially stacked on the substrate layer.

10. The electronic device of 7, wherein the first reflector layer and the second reflector layer comprise at least one of a distributed Bragg reflector layer and a high contrast grating layer.

11. The electronic device of claim 10, wherein the first electrode layer and the second electrode layer respectively comprise one N-contact layer and one P-contact layer.

12. The electronic device of claim 11, wherein the active layer comprises any one of a single quantum well layer and a multiple quantum well layer.

13. A manufacturing method for a vertical cavity surface emitting laser, wherein the method is applied to the vertical cavity surface emitting laser of claim 1, and the method comprises:
providing a substrate layer; and
forming a first reflector layer, an active layer, an oxide layer, a second reflector layer, a second electrode layer, and a passivation layer on the substrate layer, and forming the first electrode layer under the substrate layer, wherein the oxide layer is obtained by oxidizing AlₓGa₁₋ₓAs in which the aluminum composition is gradually varied, x represents aluminum composition, the aluminum composition in the middle of the oxide layer is the highest, and the aluminum composition on upper and lower sides thereof is gradually reduced.

14. The manufacturing method for a vertical cavity surface emitting laser of claim 13, wherein the first electrode layer is located under the substrate layer, and the first reflector layer, the active layer, the oxide layer, the second reflector layer, the second electrode layer, and the passivation layer are sequentially stacked on the substrate layer.

15. The manufacturing method for a vertical cavity surface emitting laser of claim 13, wherein the first electrode layer and the passivation layer are located under the substrate layer, and the first reflector layer, the active layer, the oxide layer, the second reflector layer and the second electrode layer are sequentially stacked on the substrate layer.

16. The manufacturing method for a vertical cavity surface emitting laser of claim 13, wherein the first reflector layer and the second reflector layer comprise at least one of a distributed Bragg reflector layer and/or a high contrast grating layer respectively.

17. The manufacturing method for a vertical cavity surface emitting laser of claim 16, wherein the first electrode layer and the second electrode layer respectively comprise one N-contact layer and one P-contact layer.

18. The manufacturing method for a vertical cavity surface emitting laser of claim 17, wherein the active layer comprises any one of a single quantum well layer and a multiple quantum well layer.

19. The vertical cavity surface emitting laser of claim 13, wherein AlₓGa₁₋ₓAs layer in which the content of the aluminum composition is gradually varied has a thickness ranging from 5 nm to 20 nm.
